(19) United States
(12) Patent Application Publication
(10) Pub. No.: US 2015/0229302 A1
(43) Pub. Date: Aug. 13, 2015

(54) SENSE AMPLIFIER AND METHOD OF OPERATING THE SAME

(71) Applicant: SAMSUNG ELECTRONICS CO., LTD., Suwon-si (KR)

(72) Inventors: Tae Jin KIM, Hwaseong-si (KR); Jae Youl LEE, Hwaseong-si (KR)

(21) Appl. No.: 14/556,605

(22) Filed: Dec. 1, 2014

(30) Foreign Application Priority Data
Feb. 7, 2014 (KR) 10-2014-0014326

(51) Int. Cl. H03K 5/24

(52) U.S. Cl. CPC H03K 5/2481; H03K 5/249

(57) ABSTRACT

A sense amplifier includes a differential input circuit, a floating prevention circuit, and a differential amplifier. The differential input circuit output a first current flowing through a first node according to a first input signal, and second current flowing through a second node according to a second input signal. The floating prevention circuit outputs a third current flowing through the first node according to the second input signal, and fourth current flowing through the second node according to the first input signal. The differential amplifier generates a first output signal according to the first current or the third current flowing through the first node, and a second output signal according to the second current or the fourth current flowing through the second node. The sense amplifier may be coupled to a latch to form a flip-flop circuit.

### CROSS-REFERENCE TO RELATED APPLICATIONS

Korean Patent Application No. 10-2014-0014326, filed on Feb. 7, 2014, and entitled, “Sense Amplifier and Method of Operating the Same,” is incorporated by reference herein in its entirety.

### BACKGROUND

1. Field

One or more embodiments described herein relate to a sense amplifier and a method of operating a sense amplifier.

2. Description of the Related Art

A sense amplifier may be used to amplify data received from a semiconductor integrated circuit. The sense amplifier may operate in synchronization with a clock signal generated in the semiconductor integrated circuit. The amplified data output from the sense amplifier may include noise in various formed. For example, one type of noise is based on the type of data being amplified. Another type of noise is based on skew between the input data and clock signal. The noise adversely affects the amplified data output from the sense amplifier.

### SUMMARY

In accordance with one embodiment, a sense amplifier includes a differential input circuit to output a first current flowing through a first node according to a first input signal, and second current flowing through a second node according to a second input signal; a floating prevention circuit to output a third current flowing through the first node according to the second input signal, and fourth current flowing through the second node according to the first input signal; and a differential amplifier to generate a first output signal according to the first current or the third current flowing through the first node, and a second output signal according to the second current or the fourth current flowing through the second node. The first and second input signals may have opposing logical values which alternate.

The sense amplifier may include a switch to control flow of the first current to the fourth current according to a control signal, and a pre-charging circuit to pre-charge a third node and a fourth node to a power supply voltage when the clock signal is at a first level, wherein the first output signal is output via the third node and the second output signal is output via the fourth node.

The switching circuit may block the first current to the fourth current when the clock signal is at the first level, and allows the first current to the fourth current to flow when the clock signal is at a second level.

The floating prevention circuit may cause the third current and the fourth current to flow so as to prevent the first node and the second node from having a floating state. A difference between levels of the first output signal and the second output signal may be determined according to a difference between levels of the first input signal and the second input signal.

A difference between amounts of the first current flowing through the first node and the fourth current flowing the second node may be determined by a ratio between amounts of the first current and the fourth current, and a difference between amounts of the second current flowing through the second node and the third current flowing through the third node may be determined by a ratio between amounts of the second current and the third current. Each of the first input signal and the second input signal may be a transistor-transistor logic signal.

The sense amplifier may include a coupling compensation circuit to prevent a coupling phenomenon from occurring between the first node and the second node.

In accordance with another embodiment, a semiconductor chip includes a sense amplifier according to the aforementioned embodiment.

In accordance with another embodiment, a method of operating a sense amplifier includes outputting a first current flowing through a first node according to a first input signal, and a second current flowing through a second node according to a second input signal; outputting a third current flowing through the first node according to the second input signal, and a fourth current flowing through the second node according to the first input signal; and generating a first output signal according to first current or the third current through the first node, and a second output signal according to second current or the fourth current flowing through the second node. The first and second input signals may have opposing logical values which alternate.

The method may include controlling flow of the first current to the fourth current according to a clock signal; and pre-charging a third node and a fourth node to a power supply voltage when the clock signal is at a first level, wherein the first output signal is output via the third node and the second output signal is output via the fourth node.

Controlling of the flow of the first current to the fourth current may include blocking the first current to the fourth current when the clock signal is at the first level, and allowing the first current to the fourth current to flow when the clock signal is at a second level. The third current and the fourth current may prevent the first node and the second node from having a floating state. A difference between levels of the first output signal and the second output signal may be determined according to a difference between levels of the first input signal and the second input signal.

A difference between amounts of the first current flowing through the first node and the fourth current flowing the second node may be determined by a ratio between amounts of the first current and the fourth current, and a difference between amounts of the second current flowing through the second node and the third current flowing through the third node may be determined by a ratio between amounts of the second current and the third current.

In accordance with another embodiment, an apparatus includes a differential amplifier to generate first and second output signals; a first circuit to output a first current from a first node based on first differential signal, and to output second current from a second node based on a second differential signal, the first and second nodes coupled to the differential amplifier; and a second circuit to output a third current from the first node based on the second differential signal, and a fourth current from the second node based on the first differential signal, wherein the first and fourth currents are output from the first node when a clock signal is at a first level and the second and third currents are output from the second node when the clocks signal is at a complementary second level.

The apparatus may include a first pre-charge circuit; and a second pre-charge circuit, wherein the first and second pre-charge circuits are connected to the differential amplifier and operate based on the clock signal. The apparatus may include a latch coupled to receive the first and second output signals of the differential amplifier, the differential amplifier and the latch to operate as a flip-flop circuit.

### BRIEF DESCRIPTION OF THE DRAWINGS

Features will become apparent to those of skill in the art by describing in detail exemplary embodiments with reference to the attached drawings in which:

FIG. 1 illustrates an embodiment of a sense amplifier;

FIG. 2 illustrates an embodiment of a flip-flop;

FIGS. 3A and 3B illustrate additional embodiments of a flip-flop;

FIG. 4 illustrates operation of a sense amplifier in the flip-flop of FIG. 2;

FIG. 5 illustrates a method for operating the sense amplifier of FIG. 2;

FIG. 6 illustrates another method for operating the sense amplifier of FIG. 2;

FIG. 7 illustrates an embodiment of an image sensor; and

FIG. 8 illustrates an embodiment of a memory system

### DETAILED DESCRIPTION

Example embodiments are described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

When an element is referred to as “connected” or “coupled” to another element, it may be directly connected or coupled to the other element or one or more intervening elements may be present. In contrast, when an element is referred to as being “directly connected” or “directly coupled” to another element, there are no intervening elements present. As used herein, the term “and/or” includes any and all combinations of one or more of the associated listed items and may be abbreviated as “/”.

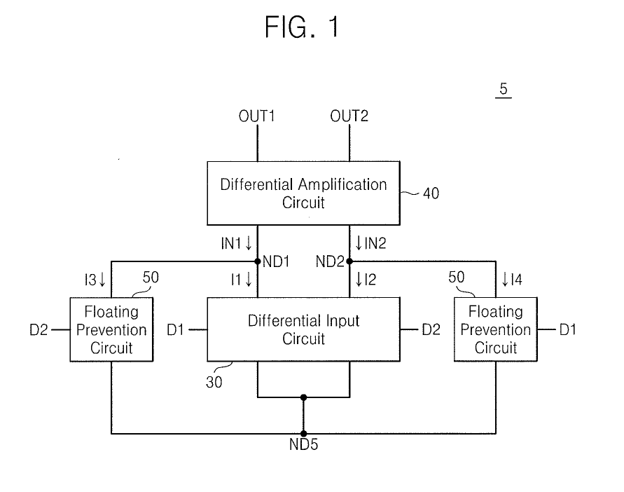

FIG. 1 illustrates an embodiment of a sense amplifier 5 for sensing a difference between levels of differential input signals D1 and D2, amplifying the sensed difference, and outputting a first output signal OUT1 and a second output signal OUT2.

The sense amplifier 5 includes a differential input circuit 30, a differential amplification circuit 40, and a floating prevention circuit 50. The differential input circuit 30 generates first current I1 flowing through a first node ND1 according to a first input signal D1, and second current I2 flowing through a second node ND2 according to a second input signal D2.

The differential amplification circuit 40 generates the first output signal OUT1 based on current IN1 from the first node ND1, and the second output signal OUT2 based on current IN2 from the second node ND2.

The floating prevention circuit 50 generates third current I3 flowing to the first node ND1 according to the second input signal D2, and fourth current I4 flowing to the second node ND2 according to the first input signal D1.

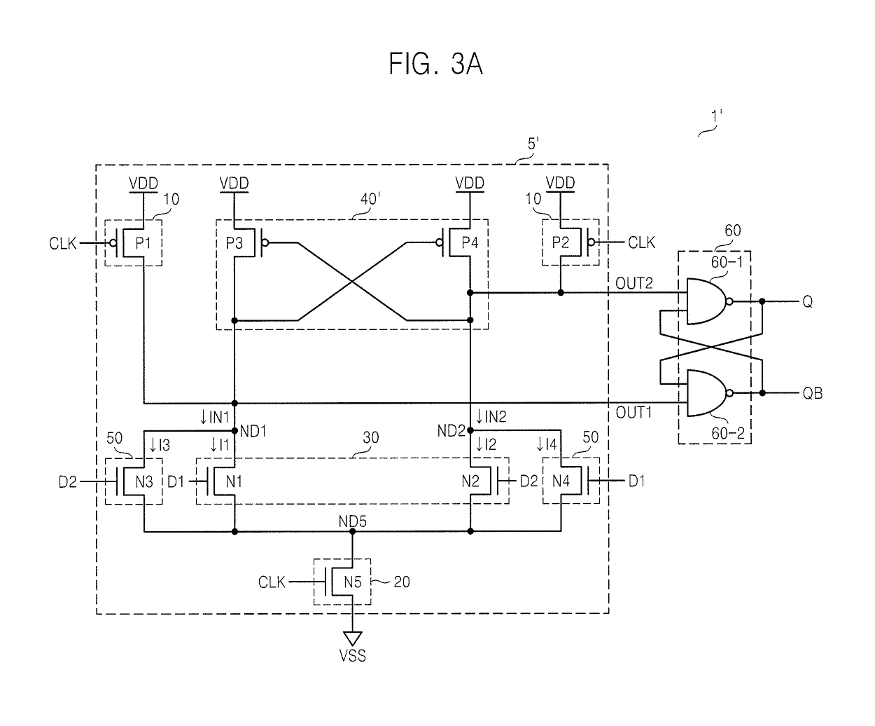

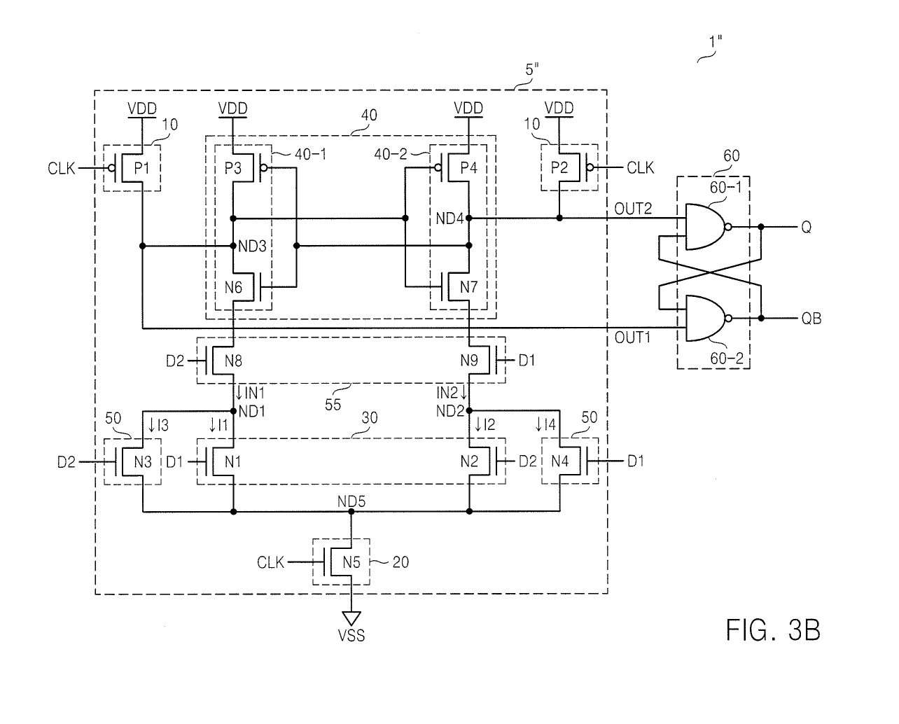

The differential amplification circuit 40 and the floating prevention circuit 50 are connected via the first node ND1, the second node ND2, and a fifth node NDS. Also, the sense amplifier 5 may optionally include a coupling prevention circuit 55 (see FIG. 3B) between the differential input circuit 30 and the differential amplification circuit 40.

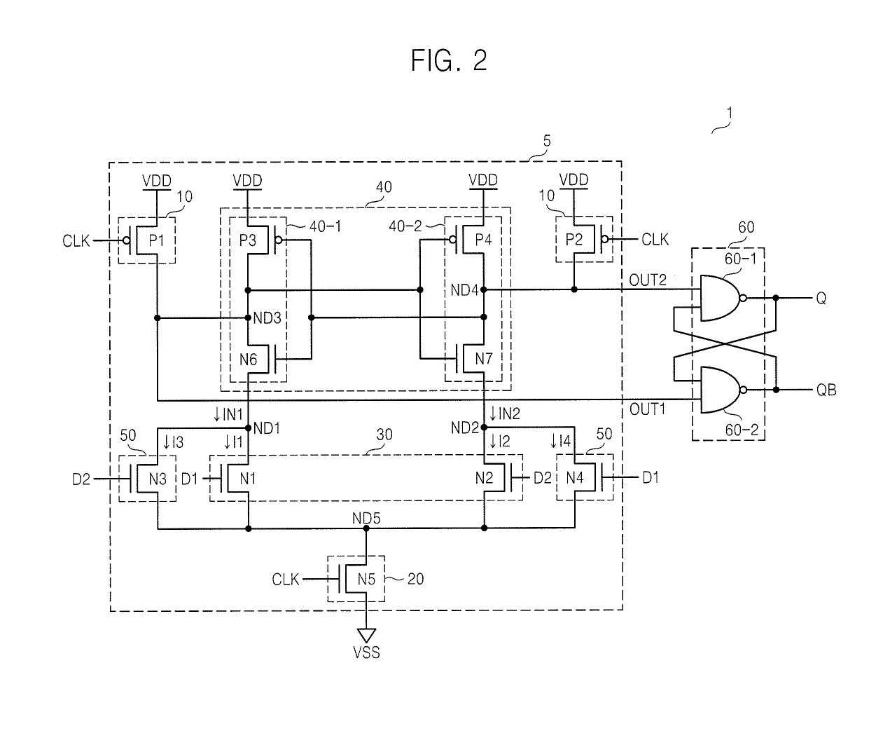

FIG. 2 illustrates an embodiment of a flip-flop 1 which includes the sense amplifier in FIG. 1. Referring to FIGS. 1 and 2, the flip-flop 1 includes the sense amplifier 5 and a latch unit 60. The flip-flop 1 may be used to restore data in a high-speed data transmission method. Additionally, the flip-flop 1 generates output signals Q and QB, which may differ by an amount equal to or based on a desired level. The output signals Q and QB are generated by sensing a difference between levels of differential input signals D1 and D2.

In accordance with one embodiment, the sense amplifier 5 includes a pre-charging circuit 10, a switching circuit 20, a differential input circuit 30, a differential amplification circuit 40, and a floating prevention circuit 50.

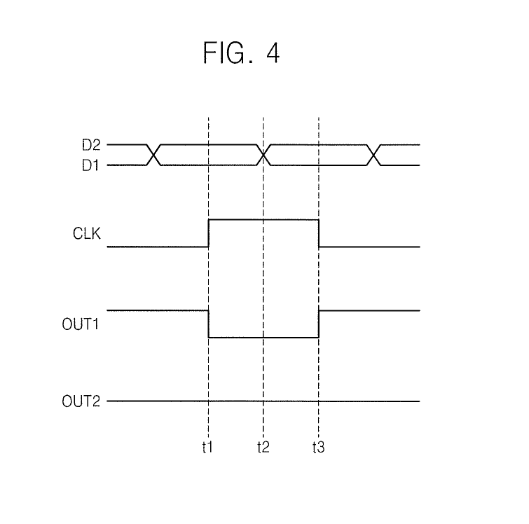

The pre-charging circuit 10 includes a first PMOS transistor P1 connected between a power supply voltage VDD source and a third node ND3, and a second PMOS transistor P2 connected between the power supply voltage VDD source and a fourth node ND4. The first PMOS transistor P1 and the second PMOS transistor P2 respectively pre-charge the third node ND3 and the fourth node ND4 to power supply voltage VDD at a falling edge of a clock signal CLK. The power supply voltage VDD is a predetermined voltage, e.g., 5 V. The first output signal OUT1 and the second output signal OUT2 are respectively output through the third node ND3 and the fourth node ND4. The pre-charging circuit 10 maintains the first output signal OUT1 and the second output signal OUT2 at a predetermined (e.g., high) level at a rising edge of the clock signal CLK, i.e., until time t1, for example, as illustrated in FIG. 4.

The switching circuit 20 may include a fifth NMOS transistor N5 between a ground voltage VSS source and a fifth node NDS. The fifth NMOS transistor N5 controls the flow of first current I1 to fourth current I4 from the differential input circuit 30 and the floating prevention circuit 50. For example, the fifth NMOS transistor N5 blocks the first current I1 to the fourth current I4 to not flow therethrough when the clock signal CLK is at a low level, and allows the first current I1 to the fourth current I4 to flow therethrough when the clock signal CLK is at a high level.

The differential input circuit 30 may include a first NMOS transistor N1 connected between a first node ND1 and the fifth node ND5, and a second NMOS transistor N2 connected between a second node ND2 and the fifth node ND5. The first NMOS transistor N1 may output the first current I1 according to a first input signal D1, and the second NMOS transistor N2 may output the second current I2 according to a second input signal D2.

The differential amplification circuit 40 may include a first inverter 40-1 connected between the power supply voltage VDD source and the first node ND1, and a second inverter 40-2 connected between the power supply voltage VDD source and the second node ND2. The first inverter 40-1 may include a third PMOS transistor P3 and a sixth NMOS transistor N6, and the second inverter 40-2 may include a fourth PMOS transistor P4 and a seventh NMOS transistor N7. Gates of the respective third PMOS transistors P3 and sixth NMOS transistor N6 may be connected to the fourth node ND4 that is an output terminal of the second inverter 40-2. Gates of the respective fourth PMOS transistor P4 and seventh NMOS transistor N7 may be connected to the third node ND3 that is an output terminal of the first inverter 40-1.

For example, the first inverter 40-1 and the second inverter 40-2 may be cross-coupled to each other. The first inverter 40-1 may output a first output signal OUT1 according to current IN1 flowing through the first node ND1. The second inverter 40-2 may output a second output signal OUT2 according to current IN2 flowing through the second node ND2. The current IN1 flowing through the first node ND1 may be the sum of the first current I1 and the third current I3. The current IN2 flowing through the second node ND2 may be the sum of the second current I2 and the fourth current I4.

The floating prevention circuit 50 includes a third NMOS transistor N3 connected between the first node ND1 and the fifth node ND5, and a fourth NMOS transistor N4 connected between the second node ND2 and the fifth node ND5. The third NMOS transistor N3 outputs the third current I3 according to the second input signal D2. The fourth NMOS transistor N4 outputs the fourth current I4 according to the first input signal D1. The ratio of sizes (e.g., the ratio between a channel width W and a channel length L) of the first NMOS transistor N1 and the third NMOS transistor N3 may be K:1. The ratio of sizes (e.g., the ratio between a channel width W and a channel length L) of the second NMOS transistor N2 and the fourth NMOS transistor N4 may be K:1. The value of K may be a positive value that is greater than 1, for example, by a predetermined amount.

The latch unit 60 includes a first NAND gate 60-1 and a second NAND gate 60-2. The first NAND gate 60-1 may receive the second output signal OUT2 and an inverted output signal QB and operate as a set/reset (SR) latch. The second NAND gate 60-2 may receive the first output signal OUT1 and an output signal Q and operate as an SR latch. For example, the latch unit 60 may latch the first input signal OUT1 and the second input signal OUT2, and output the output signal Q and the inverted output signal QB.

FIG. 3A illustrates another embodiment of a flip-flop 1′ which includes a sense amplifier 5′. Referring to FIGS. 1 and 3A, the structure and operation of the flip-flop 1′ may be substantially the same as in FIG. 2, except for a differential amplification circuit 40′ of the sense amplifier 5′.

Instead of the first inverter 40-1 and the second inverter 40-2 in FIG. 2, the differential amplification circuit 40′ includes a third PMOS transistor P3 and a fourth PMOS transistor P4 that are cross-coupled to each other. The differential amplification circuit 40′ does not include the sixth NMOS transistor N6 and the seventh NMOS transistor N7 illustrated in FIG. 2. Thus, a first output signal OUT1 is output via a first node ND1 and a second output signal OUT2 is output via a second node ND2, compared to FIG. 2 in which the first output signal OUT1 is output via the third node ND3 and the second output signal OUT2 is output via the fourth node ND4. Besides this difference, operation of the differential amplification circuit 40′ is substantially the same as the differential amplification circuit 40 of FIG. 2.

FIG. 3B illustrates another embodiment of a flip-flop 1″ which includes a sense amplifier 5″. Referring to FIGS. 1 to 3B, the structure and operation of the flip-flop 1″ may be substantially the same as FIG. 2, except for a coupling compensation circuit 55 in the sense amplifier 5″.

The coupling compensation circuit 55 includes an eighth NMOS transistor N8 connected between a first node ND1 and a sixth NMOS transistor N6, and a ninth NMOS transistor N9 connected between a second node ND2 and a seventh NMOS transistor N7. The eighth NMOS transistor N8 and the ninth NMOS transistor N9 respectively receive a second input signal D2 and a first input signal D1, as received by a third NMOS transistor N3 and a fourth NMOS transistor N4.

A coupling phenomenon may occur in a first node ND1 and a second node ND2 due to a junction capacitance between a gate and drain of each of a first NMOS transistor N1 and a second NMOS transistor N2 of a differential input circuit 30. This coupling phenomenon may occur, for example, when a transition between the first input signal D1 and the second input signal D2 (e.g., at a point in time illustrated in FIG. 4), at which the levels of the first input signal D1 and the second input signal D2 switch levels, is close to a rising edge of a clock signal CLK. For example, the coupling phenomenon at the first node ND1 may occur when a level of the first node ND1 temporarily changes (due to the junction capacitance between the gate and drain of the first NMOS transistor N1) and when the level of the first input signal D1 changes. Thus, when the coupling phenomenon occurs close to a rising edge of the clock signal CLK, each of the first node ND1 and the second node ND2 may have an undesired level, which may prevent the sense amplifier 5″ from normally operating.

As previously indicated, the sense amplifier 5″ includes the coupling compensation circuit 55. The compensation circuit 55 receives an input having a phase opposite to those of the first NMOS transistor N1 and the second NMOS transistor N2, and may have the same size as the first NMOS transistor N1 and the second NMOS transistor N2, to prevent the coupling phenomenon from occurring.

For example, the coupling compensation circuit 55 may prevent the level of the first node ND1 from increasing due to junction capacitance between the gate and drain of the eighth NMOS transistor N8 that receives the second input signal D2, the level of which decreases when the level of the first node ND1 increases due to the junction capacitance between the gate and drain of the first NMOS transistor N1 when the level of the first input signal D1 increases.

Operations of the flip-flop 1″ may be substantially the same as flip-flop 1 of FIG. 2 except for the difference described above.

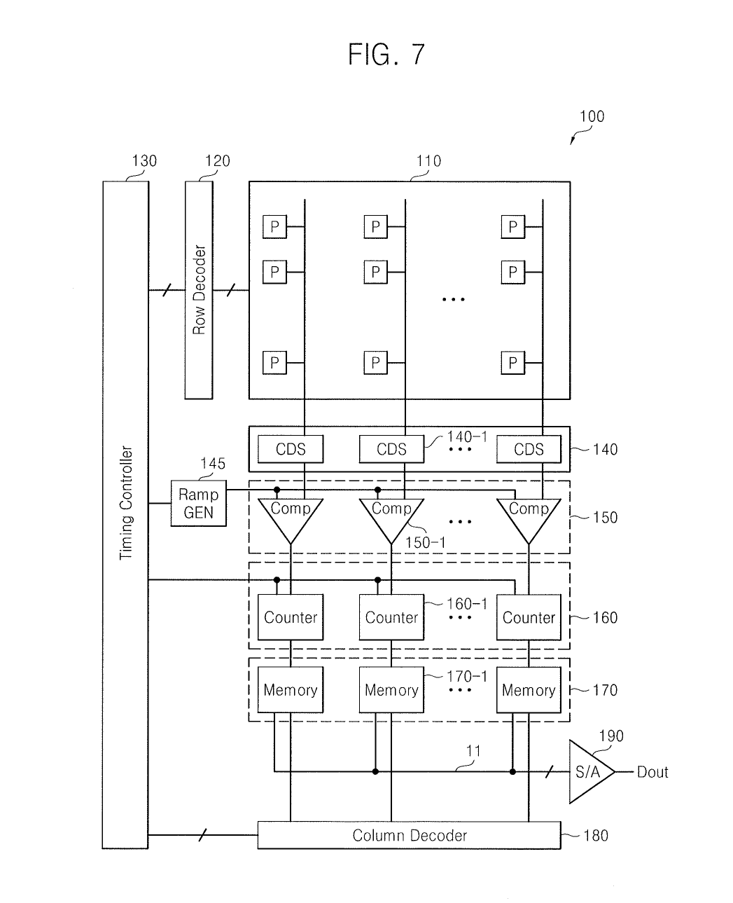

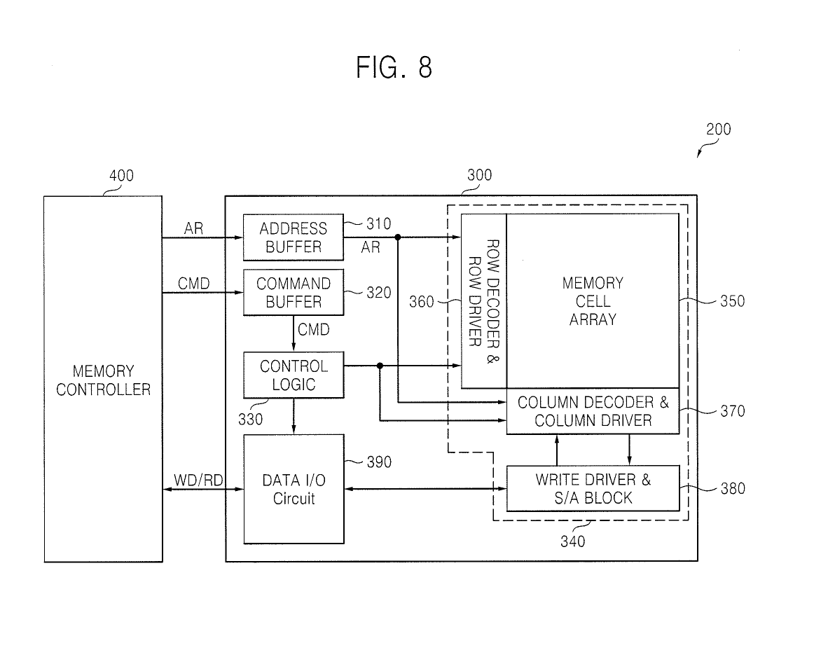

FIG. 4 is a timing diagram illustrating operation of the flip-flop 1 in FIG. 2 according to one embodiment. Referring to FIGS. 1 to 4, in accordance with one embodiment, a first input signal D1 and a second input signal D2 are differential input signals, the levels of which alternately switch between high and low levels. In another embodiment, for example, in the case of an image sensor 100 in FIG. 7 and a memory system 200 in FIG. 8, the first input signal D1 may be a pixel signal or a read out signal and the second input signal D2 may be a reference voltage.

The fifth NMOS transistor N5 is turned off before time t1. Before time t1, a clock signal CLK is at a low level in order to block the flow of first current I1 to fourth current I4. The first current I1 to fourth current I4 are blocked during this period (e.g., <t1) regardless of the levels of the first input signal D1 and the second input signal D2. Also, the first PMOS transistor P1 and the second PMOS transistor P2 are turned on to respectively pre-charge the levels of the third node ND3 and the fourth node ND4 to power supply voltage VDD. As a result, the first output signal OUT1 and the second output signal OUT2 are maintained at a high level.

When the clock signal CLK changes to a high level at time t1, the first PMOS transistor P1 and the second PMOS transistor P2 are turned off and the fifth NMOS transistor N5 is turned on. Also, D1 is at a high level at time t1. Thus, the first NMOS transistor N1 and the fourth NMOS transistor N4 are turned on to output the first current I1 and the fourth current I4, respectively. The second NMOS transistor N2 and the third NMOS transistor N3 are turned off at this time, and the second current I2 and the third current I3 are therefore not output because the second input signal D2 is at a low level.

The first current I1 and the fourth current I4 flow through the first node ND1 and the second node ND2, respectively, to drop voltages of the first node ND1 and the second node ND2. The third node ND3 and the fourth node ND4 charged to a high level, to cause the third PMOS transistor P3 and the fourth PMOS transistor P4 to be turned off The sixth NMOS transistor N6 and the seventh NMOS transistor N7 are turned on at this time. As the voltages of the first node ND1 and the second node ND2 drop, the sixth NMOS transistor N6 and the seventh NMOS transistor N7 may cause the current IN1 to flow through the first node ND1 and the current IN2 to flow through the second node ND2.

The current IN1 flowing through the first node ND1 and the current IN2 flowing through the second node ND2 cause voltages of the third node ND3 and the fourth node ND4 to respectively drop.

In this case, the ratio between the sizes of the first NMOS transistor N1 and the fourth NMOS transistor N4 is K:1. If it is assumed that K is greater than 1 by a predetermined amount, the amount of the first current I1 is higher than that of the fourth current I4. Thus, the degree to which the voltage of the third node ND3 drops is higher than the degree to which the voltage of the fourth node ND4 drops. A drop in the voltage of the third node ND3 causes the fourth PMOS transistor P4 to be turned on, in order to maintain the fourth node ND4 at a power supply voltage VDD and the second output signal OUT2 at a high level.

As the fourth node ND4 is maintained at the power supply voltage VDD, the voltage of the third node ND3 continuously drops and the first output signal OUT1 is thus maintained at a low level.

When the first input signal D1 is at a low level and the second input signal D2 is at a high level at time t2, the first NMOS transistor N1 and the fourth NMOS transistor N4 are turned off and the first current I1 and the fourth current I4 are not output. In contrast, the second NMOS transistor N2 and the third NMOS transistor N3 are turned on, because the second input signal D2 is at the high level. In this case, the third NMOS transistor N3 may output the third current I3 because the sixth NMOS transistor N6 is turned on as the fourth node ND4 is at the high level.

However, the second NMOS transistor N2 does not output the second current I2 because the seventh NMOS transistor N7 is turned off based on the level of the third node ND3. Thus, the second output signal OUT2 output from the fourth node ND4 is maintained at the high level to time t3, at which the fifth NMOS transistor N5 is turned off. Also, the third NMOS transistor N3 outputs third current I3 although the amount of the third current I3 is lower than that of the first current I1. Thus, the second output signal OUT2 output from the fourth node ND4 may be maintained at the low level at this time.

If it is assumed that the floating prevention circuit 50 is not present, the levels of the first output signal OUT1 and/or the second output signal OUT2 may not be maintained when data is changed in a section from time t1 to time t3, in which the clock signal CLK is at the high level, e.g., when the levels of the first input signal D1 and the second input signal D2 are relatively changed. For example, when the third NMOS transistor N3 is not present, the current IN1 does not flow through the first node ND1 and the first node ND1 and the third node ND3 are floated at time t2.

Voltages of the first node ND1 and the third node ND3 that are floated may be unstable due to various causes (e.g., thermal noise, a coupling effect, etc.) outside the sense amplifier 5. Thus, levels of the first output signal OUT1 and/or the second output signal OUT2 change due to external noise. As a result, noise may occur in an output signal Q and an inverted output signal QB.

Thus, the levels of the first input signal D1 and the second input signal D2 may be limited so that no node is floated. In contrast, according to one embodiment, no node may be floated even when the levels of the first input signal D1 and the second input signal D2 are not limited in the sense amplifier 5.

The output signal Q and the inverted output signal QB depend on the difference between the amounts of the current IN1 flowing through the first node ND1 and the current IN2 flowing through the second node ND2.

When the first input signal D1 and the second input signal D2 are small-signal differential input signals (e.g., when all of the first NMOS transistor N1 to the fourth NMOS transistor N4 linearly operate according to the first input signal D1 and the second input signal D2), the difference between the amounts of the current IN1 flowing through the first node ND1 and the current IN2 flowing through the second node ND2 may be expressed by Equation 1.

$$\begin{matrix}IN 1 - IN 2 = ( I 1 + I 3 ) - ( I 2 + I 4 ) \\ = [ \{ \begin{matrix}K ( \frac{W}{L} ) β ( {V}_{D 1} - {V}_{ND 5} - {V}_{TH} ) + \\ ( \frac{W}{L} ) β ( {V}_{D 2} - {V}_{ND 5} - {V}_{TH} )\end{matrix} \} ( {V}_{ND 1} - {V}_{ND 5} ) ] - \\ [ \{ \begin{matrix}K ( \frac{W}{L} ) β ( {V}_{D 2} - {V}_{ND 5} - {V}_{TH} ) + \\ ( \frac{W}{L} ) β ( {V}_{D 1} - {V}_{ND 5} - {V}_{TH} )\end{matrix} \} ( {V}_{ND 2} - {V}_{ND 5} ) ] \\ = ( K - 1 ) ( \frac{W}{L} ) β ( {V}_{D 1} - {V}_{D 2} )\end{matrix} \qquad ( 1 )$$

wherein V_{D1}, V_{D2}, V_{ND1}, V_{ND2}, V_{ND5}, V_{TH}, and β respectively denote the voltage of the first input signal D1, the voltage of the second input signal D2, the voltage of the first node ND1, the voltage of the second node ND2, the voltage of the fifth node NDS, a threshold voltage of NMOS transistors, and a characteristic coefficient of the NMOS transistors. The characteristic coefficient β=½*μₙ(mobility constant)*Cox (oxide charge).

In Equation 1, the difference between the amounts of the current IN1 flowing through the first node ND1 and the current IN2 flowing through the second node ND2 depends on K in K:1, e.g., the ratio between the sizes of the first NMOS transistor N1 and the third NMOS transistor N3 or the ratio between the sizes of the second NMOS transistor N2 and the fourth NMOS transistor N4. For example, the difference between the amounts of the current IN1 flowing through the first node ND1 and the current IN2 flowing through the second node ND2 may be determined by the ratio between the amounts of the first current I1 and the fourth current I4 and/or the ratio between the amounts of the second current I2 and the third current I3. Also, the difference between the amounts of the current IN1 flowing through the first node ND1 and the current IN2 flowing through the second node ND2 may be determined by the difference between the levels of the first input signal D1 and the second input signal D2, e.g., (V_{D1}-V_{D2}).

When the first input signal D1 and the second input signal D2 are transistor-transistor logic (TTL) signals (e.g., when the first input signal D1 is at the high level (e.g., the first input signal has a voltage of 5V) and the second input signal D2 is at the low level (e.g., the second input signal D2 has a voltage of 0 V)) in the section from time t1 to time t2, the first NMOS transistor N1 and the fourth NMOS transistor N4 may linearly operate and the second NMOS transistor N2 and the third NMOS transistor N3 may be turned off.

In this case, the difference between the amounts of the current IN1 flowing through the first node ND1 and the current IN2 flowing through the second node ND2 may be expressed by Equation 2.

$$\begin{matrix}IN 1 - IN 2 = I 1 - I 4 \\ = K ( \frac{W}{L} ) β ( {V}_{D 1} - {V}_{ND 5} - {V}_{TH} ) ( {V}_{ND 1} - {V}_{ND 5} ) - \\ ( \frac{W}{L} ) β ( {V}_{D 1} - {V}_{ND 5} - {V}_{TH} ) ( {V}_{ND 2} - {V}_{ND 5} ) \\ = ( K - 1 ) ( \frac{W}{L} ) β {V}_{D 1}\end{matrix} \qquad ( 2 )$$

In Equation 2, the difference between the amounts of the current IN1 flowing through the first node ND1 and the current IN2 flowing through the second node ND2 depends on K of K:1, e.g., the ratio between the sizes of the first NMOS transistor N1 and the fourth NMOS transistor N4. In other words, the difference between the amounts of the current IN1 flowing through the first node ND1 and the current IN2 flowing through the second node ND2 may be determined by the ratio between the amounts of the first current Il and the fourth current I4. Thus, when the first input signal D1 and the second input signal D2 are TTL signals, the sense amplifier 5 may operate so that no node is floated. Accordingly, the sense amplifier 5 may output a stable signal without floating any node.

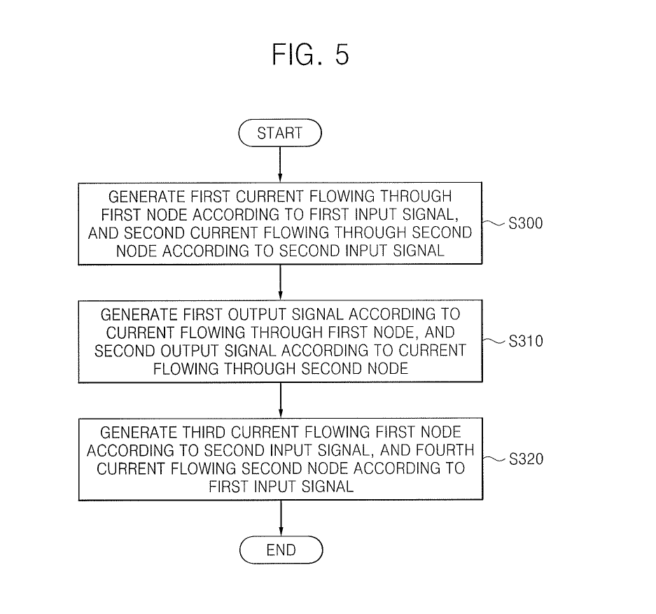

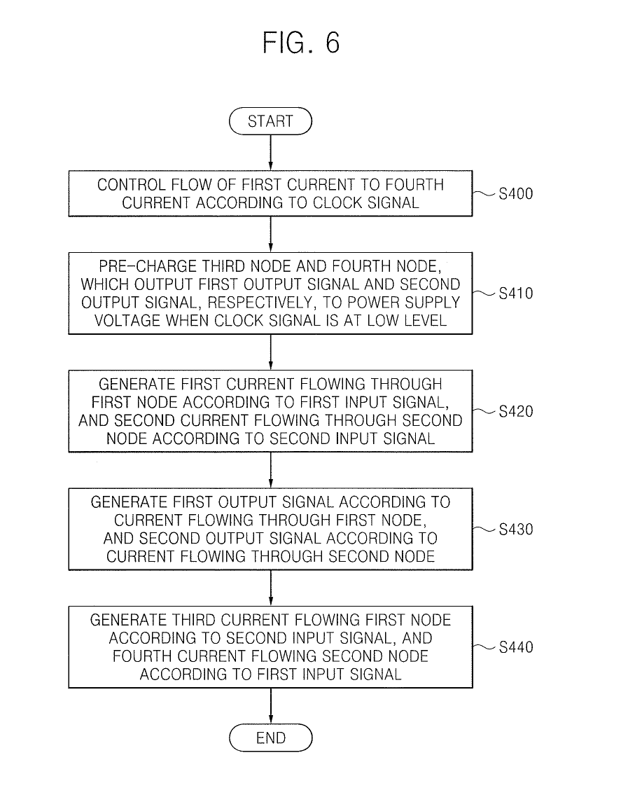

FIG. 5 illustrates an embodiment of a method for operating the sense amplifier 5 of FIG. 2, and FIG. 6 illustrates another embodiment of a method for operating the sense amplifier 5.

Referring to FIG. 5, the first NMOS transistor N1 outputs first current I1 flowing through the first node ND1 according to the first input signal D1, and the second NMOS transistor N2 outputs second current I2 flowing through the second node ND2 according to the second input signal D2 (S300).

Then, the first inverter 40-1 outputs the first output signal OUT1 according to current IN1 flowing through the first node ND1, and the second inverter 40-2 outputs the second output signal OUT2 according to current IN2 flowing through the second node ND2 (S310).

The third NMOS transistor N3 outputs the third current I3, which is 1/K of the first current I1, according to the second input signal D2. The fourth NMOS transistor N4 outputs the fourth current I4, which is 1/K of the second current I2, according to the first input signal D1 (S320).

In the method of FIG. 6, operations S420, S430, and S440 are substantially the same as operations S300, S310, and S320 of FIG. 5. Additionally, the fifth NMOS transistor N5 blocks the first current I1 to the fourth current I4 from flowing therethrough when the clock signal CLK is at a low level, and allows the first current I1 to the fourth current I4 to flow therethrough when the clock signal CLK is at the high level (S400).

The first PMOS transistor P1 and the second PMOS transistor P2 respectively pre-charge the third node ND3 and the fourth node ND4 to a power supply voltage VDD at a falling edge of the clock signal CLK (S410).

FIG. 7 illustrates an embodiment of an image sensor 100 which includes any of the aforementioned embodiments of the flip-flop. For illustrative purposes, the image sensor 100 will be described as including flip-flop 1 of FIG. 2.

Referring to FIGS. 2 and 7, the image sensor 100 (e.g., a CMOS image sensor) includes an active pixel sensor array 110, a row decoder 120, a timing controller 130, a correlated double sampling (CDS) block 140, a comparator block 150, a ramp signal generator 145, a column counter block 160, a memory block 170, a column decoder 180, and a sense amplifier 190.

The CDS block 140, the comparator block 150, the column counter block 160, and the memory block 170 may perform functions of an analog-digital converting circuit.

The active pixel sensor array 110 includes a plurality of pixels P. Each pixel P may include a photo-sensitive element that generates a pixel signal from an incident optical signal. The pixel signal may include, for example, a reset signal and an image signal.

The row decoder 120 generate a plurality of control signals for controlling light-sensing operations of the pixels P, respectively, under control of the timing controller 130. The row decoder 120 may drive the pixels, for example, in rows.

The timing controller 130 generates a plurality of control signals for controlling overall operations of the image sensor 100.

The CDS block 140 includes CDS circuits 140-1 connected to respective columns. Each CDS circuit 140-1 performs correlated double sampling on a pixel signal output from a corresponding column and outputs a correlated double sampled pixel signal.

The comparator block 150 includes a plurality of comparators 150-1 corresponding to the CDS circuits 140-1. Each comparator 150-1 compares a ramp signal output from the ramp signal generator 145 with the correlated double sampled pixel signal output from one of the CDS circuits 140-1. Each comparator 150-1 then outputs a comparison signal based on the comparison.

The column counter block 160 includes a plurality of column counters 160-1 corresponding to the comparators 150-1. Each column counter 160-1 counts a time that a level of the comparison signal output from one of the comparators 150-1 changes and outputs a count value according to a clock signal, under control of the timing controller 130.

The memory block 170 includes a plurality of memories 170-1. Each memory 170-1 stores the count value output from one of the column counters 160-1. Each memory 170-1 may be, for example, an SRAM or another type of memory device.

The column decoder 180 generates selection signals for selecting the memories 170-1, respectively, under control of the timing controller 130. For example, when the column decoder 180 outputs a selection signal activated to select a first memory 170-1, data stored in the first memory 170-1 is transmitted to the sense amplifier 190 via a data line 11. The column decoder 180 sequentially activates the selection signals to sequentially output data stored in the memories 170-1 via the data line 11.

The sense amplifier 190 may include the flip-flop 1 of FIG. 2. A pixel signal, output in the form of a digital signal via the data line 11, may be the first input signal D1. The second input signal D2 may be a reference voltage. The sense amplifier 190 may generate an output signal Dout by amplifying the difference between the pixel signal in the form of a digital signal and the reference voltage.

FIG. 8 illustrates an embodiment of a memory system 200 which includes a memory device 300 and a memory controller 400. The memory device 300 may include an address buffer 310, a command buffer 320, a control logic 330, a data storing unit 340, and a data input/output (I/O) circuit 390.

The address buffer 310 may receive address information AR from the memory controller 400, temporarily store the address information AR, and transmit the address information AR to the data storing unit 340, under control of the control logic 330.

The command buffer 120 may receive a command CMD from the memory controller 400, temporarily store the command CMD, and transmit the command CMD to the control logic 330, under control of the control logic 330.

The control logic 330 may control overall operations of the memory device 300.

The control logic 330 may include a command decoder, a clock generator, and a mode register set (MRS) circuit.

The data storing unit 340 may include a memory cell array 350, a row decoder & row driver 360, a column decoder & column driver 370, and a write driver & sense amplifier (S/A) block 380.

The memory cell array 350 includes word lines, bit lines, and memory cells, each of which is connected to one of the word lines and one of the bit lines. The memory cells may store at least 1-bit data. The memory cells may be, for example, a non-volatile memory for storing data regardless of whether power is supplied thereto, or a volatile memory for storing data while power is supplied thereto.

A method of physically cutting a fuse using laser or a method of electrically programming the memory cells may be used to store data in the memory cells. For example, each of the memory cells may be a dynamic random access memory (DRAM), a static RAM (SRAM), an electrically erasable programmable read-only memory (EEPROM), a flash memory, a magnetic RAM (MRAM), a conductive bridging RAM (CBRAM), a ferroelectric RAM (FeRAM), a phase-change RAM (PRAM), or a resistive RAM (RRAM or ReRAM).

The row decoder & row driver 360 may perform an operation of selecting one of the word lines and an operation of driving the selected word line with a desired operating voltage, based on the address information AR output from the address buffer 310.

The column decoder & column driver 370 may control a connection between each of the bit lines and the write driver & S/A block 380, based on the address information AR output from the address buffer 310.

The write driver & S/A block 380 may generate a current signal corresponding to write data WD based on the write data WD received from the data I/O circuit 390. The write driver & S/A block 380 may supply the current signal to at least one bit line connected to the column decoder & column driver 370. The write driver & S/A block 380 may sense and amplify a signal output from at least one bit line connected to the column decoder & column driver 370, generate read data RD corresponding to the sensed and amplified signal, and transmit the read data RD to the data I/O circuit 390.

The write driver & S/A block 380 may include the sense amplifier flip-flop 1 of FIG. 2. The signal output from the at least one bit line may be the first input signal D1, and the second input signal D2 may be a reference signal.

The data I/O circuit 390 may include a data input circuit and a data output circuit connected to a data I/O terminal.

The memory controller 400 may transmit various commands CMD for controlling operations of the memory device 300, and address information AR regarding the memory cell array 350 that performs a read operation, a write operation, or a test to the memory device 300. Also, the memory controller 400 may transmit the write data WD, which is to be written to the memory cell array 350, to the memory device 300, and receive the read data RD from the memory device 300.

In accordance with one or more of the aforementioned embodiments, a sense amplifier outputs a stable signal without floating any node. The sense amplifier may be included in a flip-flop circuit, which may be used in any number of a variety of electronic devices which require data processing.

Example embodiments have been disclosed herein, and although specific terms are employed, they are used and are to be interpreted in a generic and descriptive sense only and not for purpose of limitation. In some instances, as would be apparent to one of skill in the art as of the filing of the present application, features, characteristics, and/or elements described in connection with a particular embodiment may be used singly or in combination with features, characteristics, and/or elements described in connection with other embodiments unless otherwise indicated. Accordingly, it will be understood by those of skill in the art that various changes in form and details may be made without departing from the spirit and scope of the present invention as set forth in the following claims.

1. A sense amplifier, comprising:
a differential input circuit to output a first current flowing through a first node according to a first input signal, and second current flowing through a second node according to a second input signal;
a floating prevention circuit to output a third current flowing through the first node according to the second input signal, and fourth current flowing through the second node according to the first input signal; and
a differential amplifier to generate a first output signal according to the first current or the third current flowing through the first node, and a second output signal according to the second current or the fourth current flowing through the second node.

2. The sense amplifier as claimed in claim 1, further comprising:
a switch to control flow of the first current to the fourth current according to a control signal; and
a pre-charging circuit to pre-charge a third node and a fourth node to a power supply voltage when a clock signal is at a first level, wherein the first output signal is output via the third node and the second output signal is output via the fourth node.

3. The sense amplifier as claimed in claim 2, wherein the first and second input signals have opposing logical values which alternate.

4. The sense amplifier as claimed in claim 2, wherein the switch blocks the first current to the fourth current when the clock signal is at the first level, and allows the first current to the fourth current to flow when the clock signal is at a second level.

5. The sense amplifier as claimed in claim 1, wherein the floating prevention circuit causes the third current and the fourth current to flow so as to prevent the first node and the second node from having a floating state.

6. The sense amplifier as claimed in claim 1, wherein a difference between levels of the first output signal and the second output signal is determined according to a difference between levels of the first input signal and the second input signal.

7. The sense amplifier as claimed in claim 1, wherein:
a difference between amounts of the first current flowing through the first node and the fourth current flowing the second node is determined by a ratio between amounts of the first current and the fourth current, and
a difference between amounts of the second current flowing through the second node and the third current flowing through the third node is determined by a ratio between amounts of the second current and the third current.

8. The sense amplifier as claimed in claim 1, wherein each of the first input signal and the second input signal is a transistor-transistor logic signal.

9. The sense amplifier as claimed in claim 1, further comprising:
a coupling compensation circuit to prevent a coupling phenomenon from occurring between the first node and the second node.

10. A semiconductor chip comprising the sense amplifier as claimed in claim 1.

11-17. (canceled)

18. An apparatus, comprising:
a differential amplifier to generate first and second output signals;
a first circuit to output a first current from a first node based on first differential signal, and to output second current from a second node based on a second differential signal, the first and second nodes coupled to the differential amplifier; and
a second circuit to output a third current from the first node based on the second differential signal, and a fourth current from the second node based on the first differential signal, wherein the first and fourth currents are output from the first node when a clock signal is at a first level and the second and third currents are output from the second node when the clock signal is at a complementary second level.

19. The apparatus as claimed in claim 18, further comprising:
a first pre-charge circuit; and
a second pre-charge circuit,
wherein the first and second pre-charge circuits are connected to the differential amplifier and operate based on the clock signal.

20. The apparatus as claimed in claim 18, further comprising:
a latch coupled to receive the first and second output signals of the differential amplifier, the differential amplifier and the latch to operate as a flip-flop circuit.
